(19) United States
(12) Patent Application Publication
(10) Pub. No.: US 2009/0123662 A1
(43) Pub. Date: May 14, 2009

(54) Plasma Coating Device and Method

(76) Inventor: Stefan Laure, Stuttgart (DE)

Correspondence Address: Orum & Roth, 53 W. Jackson Blvd, Chicago, IL, 60604-3606, US

(21) Appl. No.: 11/918,187

(22) PCT Filed: Apr. 11, 2006
(86) PCT No.: PCT/DE2006/000638

§ 371 Date: Jan. 22, 2009

(30) Foreign Application Priority Data
Apr. 11, 2005 (DE) 10 2005 016 582.6

(51) Int. Cl. C23C 16/513

(52) U.S. Cl. 427/569; 118/723 R

(57) ABSTRACT

This invention relates to an apparatus and a method for the plasma coating of large-volume parts. For this purpose, a vacuum chamber (3) with one or more pumps, a transport apparatus (2) for the conveyance of the parts (1, 17) into the vacuum chamber (3), insulation (4) between the part (1, 17) and the vacuum chamber (3), an oscillating circuit with a high frequency generator (5), an adjustable capacitance and an adjustable inductance of the oscillating circuit, at least one connection to connect the oscillating circuit with the part (1) and at least one plasma torch (19) connected to the vacuum chamber (3) are provided for the preparation of a coating material for the part (1, 17).

### BACKGROUND OF THE INVENTION

This invention relates to an apparatus and a method for the plasma coating of large-volume parts by means of a high-frequency electromagnetic field.

If the surface of a part is exposed to a plasma, the functionality and characteristics of the surface can be influenced and modified in a controlled manner by an appropriate selection of the plasma parameters such as pressure, temperature and plasma composition. The prior art describes methods for the treatment, modification or coating of a surface made of an arbitrary material that use particle or energy currents from a plasma. These methods include, among others, plasma spraying, plasma arc cutting, plasma heat treatment processes, plasma CVD processes and plasma cleaning. The functionality of workpiece surfaces is modified by a targeted application of plasma particles. This can be achieved by the interaction with particles with defined chemical properties or by the application of radiation which is emitted by the plasma. In processes for the plasma coating of a part, the coating material is transformed by the addition of energy into the vapor or gas state and particles are deposited from the vapor or gas phase.

A plasma torch is used for the generation of a plasma. With the plasma arc torch, a flowing gas is ionized by an arc and heated to temperatures from 10,000 to 20,000 K. In a high-frequency plasma torch, the flowing gas is ionized by the application of a high-frequency electromagnetic field to a cylindrical coil. A relatively dense plasma with a high energy density is formed in a cylindrical discharge vessel which is manufactured from a dielectric material. Here, too, plasma temperatures of up to 20,000 K can be achieved.

The thermal plasmas described above are suitable for the processing of parts that are characterized by certain stability at high temperature. Methods of this type cannot be used on parts that are made of plastic or parts that have already been painted or otherwise coated and can be exposed to a maximum temperature of only 100-200° C.

Of course, a plasma treatment of the type described above is appropriate for small parts, but it is not suitable for use on large parts. The plasma occurs only in a limited area and is not formed over the entire part. For plasma treatment of the entire surface of a large part, the plasma beam must be guided over the part, which is both time-consuming and expensive on parts such as the body parts of motor vehicle, for example.

High frequency generators are also used for the generation of thin plasmas with relatively low energy densities. Their frequency range is between several hundred kilohertz and several tens of gigahertz. The plasma is generated in the form of the source on the surfaces of electrodes or antennas and is propagated in the space. The coating material is released by sputtering from a sputter target or in Physical Vapor Deposition (PVD) methods; it is vaporized and then deposited on the part. One disadvantage of this method is that the composition and the temperature of the plasma change with the distance from the plasma torch.

The deposition of a uniform layer on the entire surface of the part is thereby made more difficult. With this method, moreover, only coatings that consist of a limited number of coating materials can be produced.

One disadvantage of the plasma treatment of the entire surface of a large part with the PVD process is that the average free path length must be long and the pressure in the vacuum chamber must be very low. Due to the size of the vacuum chamber, which is related to the size of the part, this method involves a great deal of technical effort and expense.

The methods of the prior art are also not suitable for the treatment of gaps, joints, cavities and undercuts that occur on body parts for motor vehicles. The surfaces that face away fro the plasma source are not exposed to uniform plasma. Even on the surfaces facing the plasma source, a uniform processing cannot be guaranteed due to the severe gradients. That is especially true for machining methods that are dominated by radiation processes.

### THE INVENTION AND ITS ADVANTAGES

By contrast, the apparatus claimed by the invention having the features described in claim 1 and the method claimed by the invention having the features described in claim 15 has the advantage that large parts can be subjected to a uniform plasma treatment over the entire surface and can be provided with a uniform coating. The treatment and coating includes both the exterior and the interior surfaces. Gaps, joints, cavities and undercuts are also processed.

Areas of this type occur in particular on parts that are composed of a plurality of elements.

The apparatus claimed by the invention and the method claimed by the invention can be used on any desired parts of different sizes. They are suitable in particular for use on large parts such as vehicle body parts, aircraft and machine parts, to cite just a few examples. One requirement is that the vacuum chamber must be of the necessary size and the transport apparatus must be suitable for the part.

The part is introduced into a vacuum chamber of the device for plasma coating. Then the part is connected to an oscillating circuit with a high frequency generator. For this purpose, either one pole or two poles of the oscillating circuit are connected with the part. In the first case the second pole is grounded. The part thereby forms a component of the oscillating circuit. The high-frequency alternating current flows through the part. The inductance and capacitance of the part influence the inductance and the capacitance of the oscillating circuit. To ensure the optimum coupling of the electric power to the part, the oscillating circuit, which consists of the part to be processed and its own capacitances and inductances, must be appropriately adjusted. This adjustment is made by varying the capacitances and inductances of the oscillating circuit. The setting of the capacitances and inductances of the oscillating circuit can be done either manually or automatically. With an automatic adjustment, first the capacitance and inductance of the part are determined. The variation of the capacitances and inductances of the oscillating circuit effects a modification of the frequency. As soon as the parameters [of the] oscillating circuit are set so that a plasma burns on the surface of the part, an additional plasma torch which is connected to the vacuum chamber is ignited and the coating material or materials are introduced into the plasma beam. The plasma beam provided with the coating materials then expands into the vacuum chamber and enters into interaction with the plasma in the area surrounding of the part. A homogeneous and uniform coating of the coating materials is thereby deposited on the entire surface of the part.

Depending on the size, shape and number of the parts, one or more plasma torches can be located on the vacuum chamber. For this purpose, a plurality of openings can be provided on the vacuum chamber for the connection of the plasma torches. The openings can be closed with flanges if they are not to be used.

Various processes can be performed on the part using the apparatus claimed by the invention and the method claimed by the invention. As a result of the chemical action of the plasma particles, a chemical processing of the surface of the part can be performed before the plasma coating. The physical characteristics of the surface can be influenced by the plasma radiation. These applications include the cross-linking of UV coatings, for example. As a result of the formation of surface discharges, electrical effects occur on the surface that can be used for the processing of the surface.

In contrast to electrode systems, the distance from the electrodes to the part need not be set. The plasma is generated by the formation of eddy currents on the surface of the part.

The alternating current flowing through the part produces oscillating magnetic fields which are propagated as a function of the geometry of the part in its environment. The change of the magnetic field over time leads to electric fields which are responsible for the generation and maintenance of the plasma in the vicinity of the part.

The plasma which is generated by means of the oscillating circuit on the surface of the part has a relatively low energy density. The temperature connected with the plasma is generally not sufficient by itself to vaporize a coating material. The additional plasma torch ensures that any desired coating materials can be made available in the vapor or gas phase. Whether a material can be used as a coating material is not a function of the boiling temperature but of the energy density in the additional plasma burner. Examples of coating materials are titanium dioxide, titanium-H-butoxide, ceramic, zirconium chloride and oxychloride. The coating materials in the solid, liquid or gaseous state can be introduced into the plasma of the plasma torch via the feed devices. The coating materials can thereby be present in pure form or in the form of a chemical compound in combination with other substances. Solid coating materials can also be present in solution. That ensures an additional expansion of the spectrum of potential coating materials.

The additional plasma torch is preferably a plasma arc torch with a cathode and an anode. In the plasma arc torch the assist gas is first heated to a very high temperature. Then the coating material or materials is/are mixed into the plasma ignited between the cathode and anode. The temperature and the pressure that prevail in the plasma torch are set according to the chemical requirements that are a function of the respective coating. This can be done, for example, by the selection of the gas flow, the output of the direct current and a suitable contour of the flow channel in the plasma torch. Temperatures of 10,000 to 20,000 Kelvin can be reached in the center of the beam of the plasma torch.

In one advantageous configuration of the invention, the transport apparatus for the introduction of the part into the vacuum chamber has one or more rails and a drive system. The rails can thereby be matched to the part. On the rails or in the vicinity of the rails there is electrical insulation to insulate the part from the vacuum chamber.

In an additional advantageous configuration of the invention the oscillating circuit has high-frequency lines. On the vacuum chamber there are bushings with electrical insulation for the passage of the high-frequency lines.

In an additional advantageous configuration of the invention, there are metal sheets, tubes and/or grids in the vacuum chamber. The part represents an antenna from which electromagnetic waves are emitted into the space of the vacuum chamber. This effect can be promoted by additional antenna-like elements in the vicinity of the part. These antenna-like elements include sheets or grids made of metal. Spiral-shaped tubes made of copper, for example, can also create this effect. The electromagnetic waves are injected into these parts and ensure an additional plasma generation at a certain distance from the part.

In this manner, the flow of the radiation of the plasma toward the part can be controlled.

In an additional advantageous configuration of the invention, the plasma arc torch has a plurality of expansion stages for the admixture of various coating materials. Each expansion stage has a feed device for the introduction of a gas, a liquid and/or a powder into the plasma. The various expansion stages are located one after the other in the direction of flow of the plasma beam. The cross sections of the various expansion stages can thereby be different. In one advantageous configuration, the cross section increases in the beam direction from one expansion stage to the next. The selection of a suitable expansion ratio also ensures that the plasma provided with the coating materials flows into the vacuum chamber and not toward the cathode of the plasma torch. During the expansion from the plasma torch into the vacuum chamber, the plasma beam cools before it interacts with the plasma on the part.

In an additional advantageous configuration of the invention, a mixing chamber is provided adjacent to the expansion stages in the direction of flow. In the mixing chamber, a mixing of the different coating materials is achieved by the turbulence of the plasma beam. The plasma torch can thereby form a double de Laval nozzle together with the mixing chamber. The cross section of the mixing chamber decreases in the direction of flow before widening again and then becoming narrower once again.

In an additional advantageous embodiment of the invention, the mixing chamber is connected as the anode or is connected to the same potential as the anode. The temperature in the plasma torch is thereby kept at a high level. In this manner, the chemical reactions in the plasma torch can also be controlled.

In an additional advantageous configuration of the invention, an assist gas is dispensed into the vacuum chamber. The pressure in the vacuum chamber can thereby be increased. Pressures up to 1,000 Pa, for example, are possible. The assist gas interacts chemically with the surface of the part. The assist gases used can be a number of different gases, depending on the requirements.

In an additional advantageous configuration of the invention, an additional fluid is vaporized and dispensed into the vacuum chamber via a valve. The liquid vapor performs the same task as the assist gases.

In an additional advantageous configuration of the invention, an alternating current voltage at 0.1 to 10 MHz is fed into the oscillating circuit by means of the high frequency generator. The AC voltage is particularly preferably between 1 and 4 MHz.

In an additional advantageous configuration of the invention, the vacuum chamber is evacuated to a pressure between 0.05 and 1,000 Pa. In contrast to the methods described in the prior art, the operating pressure can be increased to several 10 mbar depending on the application. Thus an additional tool is available to control the number of particles that interact with the surface of the part to be processed.

Additional advantages and advantageous configurations of the invention are presented in the following descriptions, the accompanying drawings and the claims.

### DRAWING

The accompanying drawing illustrates one embodiment of an apparatus for plasma coating claimed by the invention, which is explained in greater detail below. In the drawings:

FIG. 1 Apparatus for plasma coating in a head-on view,

FIG. 2 Apparatus for plasma treatment in a view from overhead,

FIG. 3 Circuit diagram of the apparatus illustrated in FIGS. 1 and 2,

FIG. 4 Apparatus for plasma treatment in a view from the side,

FIG. 5 Plasma arc torch in longitudinal section,

FIG. 6 Schematic diagram of the plasma arc torch illustrated in FIG. 5.

### DESCRIPTION OF THE EXEMPLARY EMBODIMENT

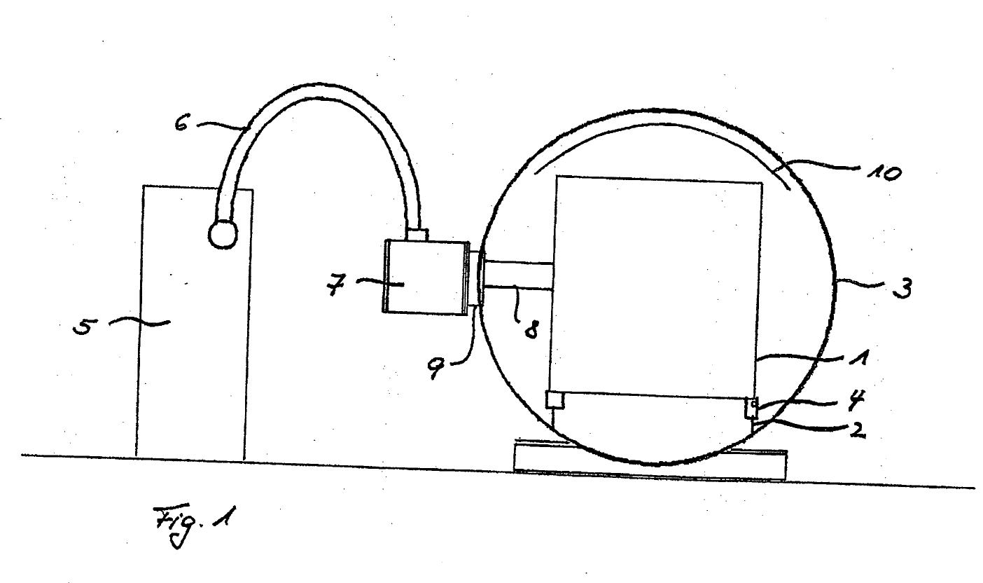

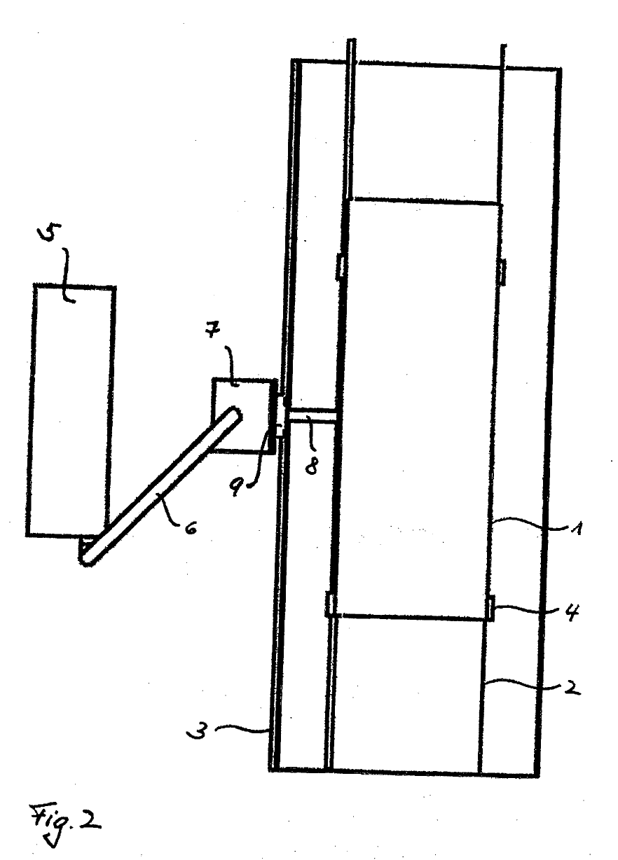

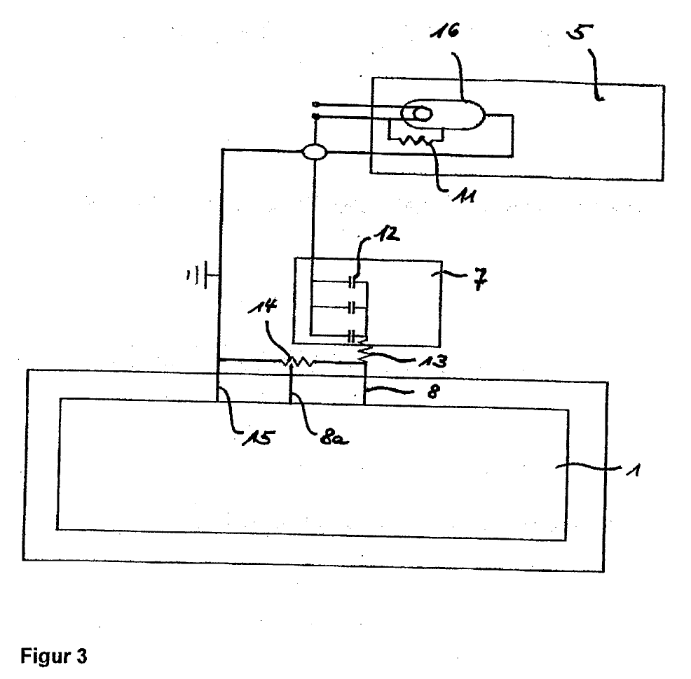

FIGS. 1 and 2 show an apparatus for plasma coating in a head-on view and a view from overhead, respectively. A part 1 to be processed is introduced into a vacuum chamber 3 via rails 2 and rollers not visible in the drawing. On the rails 2 there is insulation 4 which insulates the part 1 from the vacuum chamber. When it reaches its terminal position, the contact between a high frequency oscillating circuit and the part is closed. This is done by means of a sliding contact not visible in the drawing and which adheres to the part 1 by an interlocking fit. The part is now a part of the oscillating circuit. The oscillating circuit, apart from the part 1, consists of a high frequency generator 5 with a feedback coil 11 shown in FIG. 3, a coaxial cable 6, an external oscillating circuit 7 and a high frequency supply lead 8, on the ends of which the sliding contact is provided. In the vacuum chamber 3 there is a high frequency insulated bushing 9 for the high frequency supply lead 8. Above the part is a reflector 10 for the plasma.

FIG. 3 shows schematically the circuit diagram of the apparatus illustrated in FIGS. 1 and 2. The circuit makes possible the optimization of the plasma treatment. The high frequency generator 5 supplies the oscillating circuit with AC current by means of a coaxial cable 6. The high frequency generator 5 has a feedback coil 11, the inductance of which can be adjusted automatically. In the external oscillating circuit 7 there are three capacitances 12, all or some of which can be integrated into the oscillating circuit to modify the total capacitance. The inductance of the oscillating circuit is determined essentially by the part 1. The part 1 is connected with the external oscillating circuit 7 via the high frequency supply lead 8. To coordinate the inductance of the oscillating circuit with the part, a coil 13 is provided on the external oscillating circuit. There is also an additional coil 14 with a tap on the high frequency supply lead 8 directly on the coil 13. This coil is integrated only if necessary to adjust the total inductance in the oscillating circuit. For this case, in place of the high frequency supply lead 8, the high frequency supply lead 8a is used. The part 1 can optionally be grounded via the ground line 15.

The contact between part 1 and the oscillating circuit is verified by supplying a high frequency AC current with very low power. If the contact meets the requirements, the vacuum chamber 3 is evacuated. After the pressure in the vacuum chamber 3 has reached a certain value which is a function of the type of treatment being performed, high frequency alternating current is fed into the oscillating circuit. The plasma that is required for the treatment of the part is formed on the surface of the part 1. The effect of the plasma on the surface of the part is controlled by the regulation of the anode voltage of a transmitting tube 16 which supplies the alternating current into the oscillating circuit. The transmitting tube is not shown in the drawing. The efficiency of the injection of the electric power into the plasma is controlled by monitoring the current-voltage characteristic of the transmitting tube 16 of the oscillating circuit. The fine tuning of the oscillating circuit during the plasma treatment is accomplished by varying the inductance of the feedback coil of the oscillating circuit. Prior to the fine tuning, it is also possible to perform a rough tuning of the system by introducing additional inductances 14 or capacitances 12 into the oscillating circuit on the part to be processed.

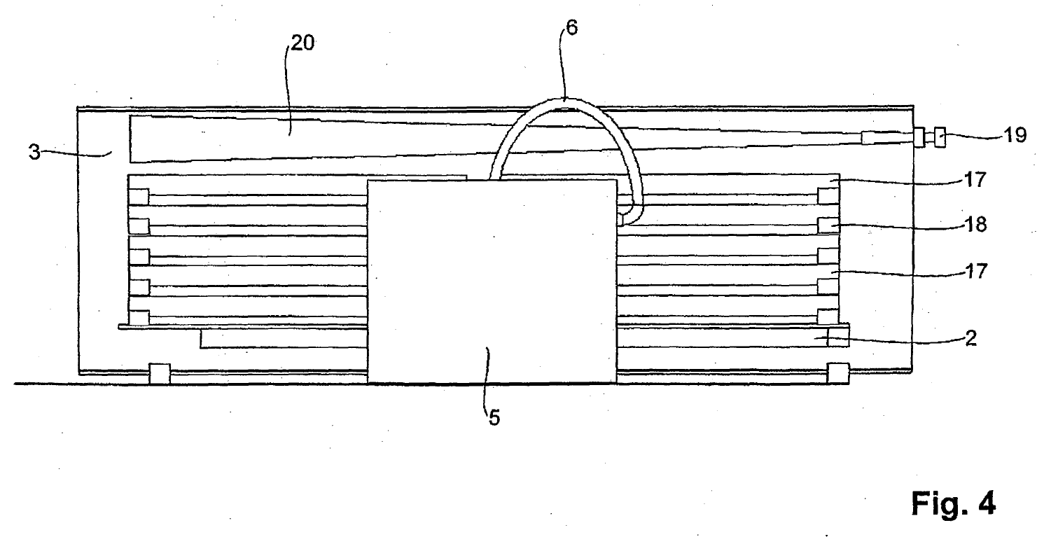

FIG. 4 shows the apparatus for plasma coating illustrated in FIGS. 1 and 2 in a view from the side. In contrast to the illustrations in FIGS. 1 and 2, in the illustration presented in FIG. 3 there are a plurality of parts 17 located one above another in the vacuum chamber 3. A rack 18 that stands on the rails 2 is used for the arrangement of the parts. In this illustration, the plasma arc burner 19 which generates the plasma beam 20 is visible. The plasma beam 20 extends above the parts 17 in the vacuum chamber. The beam profile of the plasma beam 20 becomes wider as the distance from the plasma arc torch 19 increases. The widening of the plasma beam 20 is a function of the pressure ratio between the pressure in the plasma torch and the pressure in the vacuum chamber. When there are large pressure differences, the plasma beam becomes so much wider that all or some of the parts are located in the plasma beam of the plasma torch. If that is not possible because of the boundary conditions, a second or third plasma torch can also be connected to the vacuum chamber if necessary.

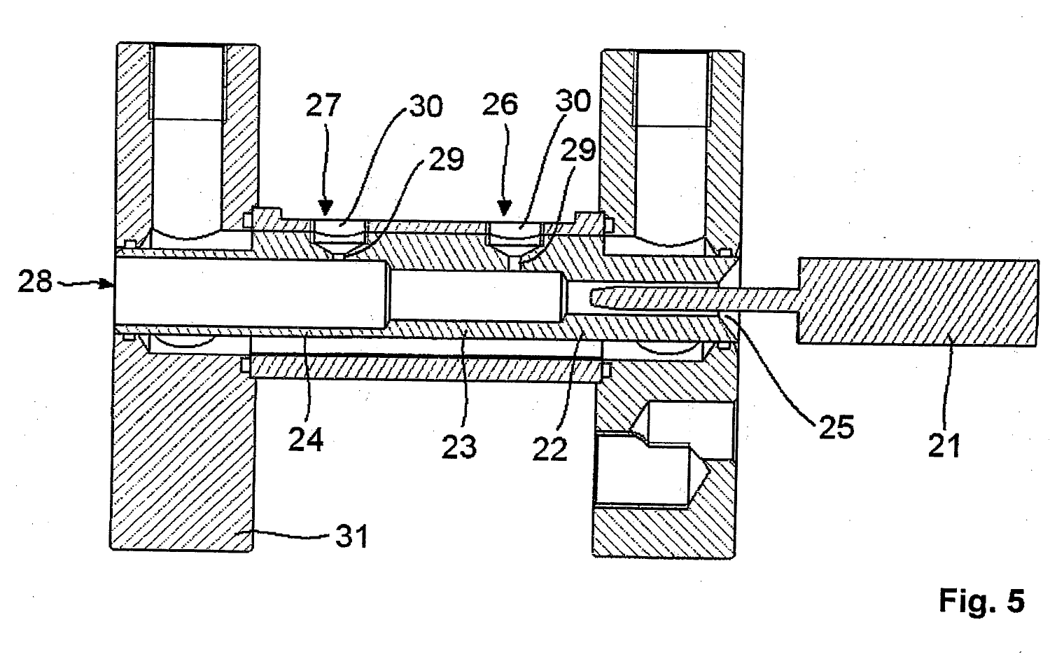

FIG. 5 shows the plasma torch 19 with a cathode 21, an anode 22 and two expansion stages 23 and 24. The cathode is in the shape of a cylinder with a cone on its forward end. The anode 22 is tubular and surrounds the cathode 21. The cathode 21 and anode 22 run coaxially to each other. The gas to be ionized is injected via the slot-shaped nozzle 25 between the anode and the cathode. In the first expansion stage 23, a first coating material is introduced via a feed device 26 into the plasma ignited by an arc between the anode 22 and the cathode 21. In the second expansion 24, a second coating material is introduced via a feeder device 27 into the plasma ignited by an arc between the anode 22 and the cathode 21. The feeder devices 26 and 27 are also called precursor feeds. They consist of a recess 29 that runs perpendicular to the axis of the anode and the cathode and a funnel-shaped segment 30. Depending on the application, the recess and the funnel-shaped segment also run at a non=90° angle with respect to the axis of the anode and cathode. The coating materials can also be introduced tangentially to the axis of the anode and cathode in the form of an eddy. A tube or hose with a powder conveyor, a dosing pump or a dosing valve can be connected to the funnel-shaped segment 30. These latter devices are not shown in the drawing.

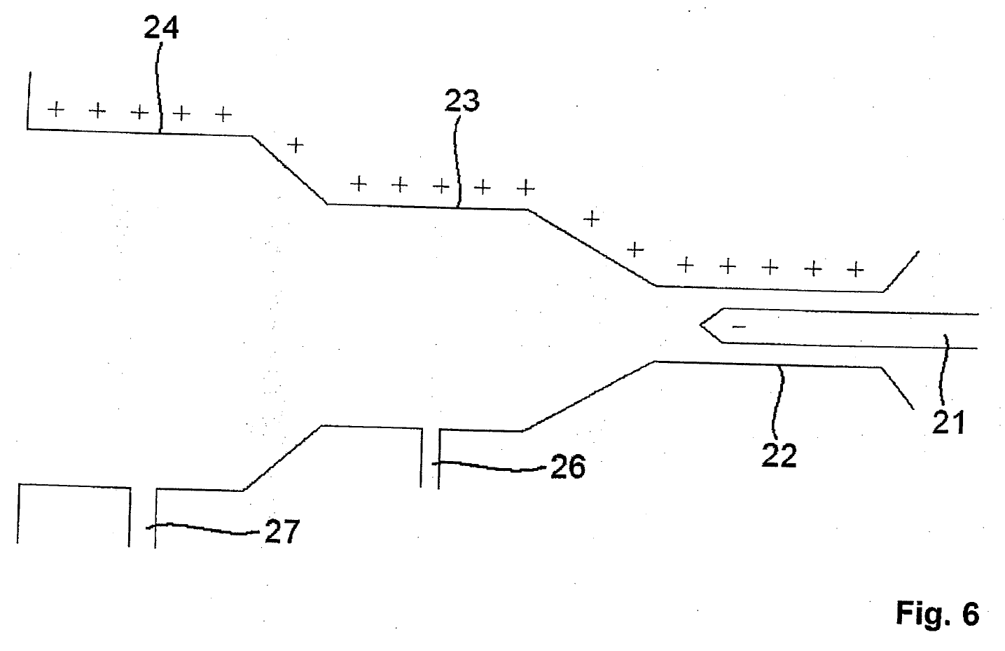

The two expansion stages differ from each other in terms of their opening cross section. The inside diameter of the second expansion stage 24 is greater than the inside diameter of the first expansion stage 23. This measure prevents the coating materials introduced through the feeder devices 26 and 27 from flowing back to the cathode 21. The plasma beam 20 provided with the coating materials exits the plasma arc burner 19 at the opening 29 and arrives in the vacuum chamber 3. For this purpose, the plasma arc torch 19 is fastened with its fastening part 3 directly to the vacuum chamber 2. To maintain the high temperature of the plasma up to the opening 28, the first and second expansion stages 23 and 24 are at the [same] potential as the anode 22. This arrangement is illustrated in FIG. 6. In the plasma arc torch 19 illustrated in FIG. 5, the anode 22, the first expansion stage 23 and the second expansion stage 24 are fabricated in one piece. It is also possible, however, to provide separate parts for this purpose which can be connected with one another. The result of that arrangement is a modular construction. In that case, the individual expansion stages can be combined, depending on the application and coating material.

The plasma arc torch 19 is ignited as soon as plasma generated by the oscillating circuit and the high frequency generator 5 has spread over the parts 17 in the vacuum chamber 3. The plasma beam 20 of the plasma arc torch 19 provided with the coating materials expands through the opening 28 into the vacuum chamber. It interacts with the plasma on the parts 17. The result is a uniform deposition of the coating materials on the surfaces of the parts 17. As soon as a layer of the desired thickness has formed on the surface, the plasma arc torches 19 and the high frequency generator 5 are turned off. Depending on the application and coating materials, first the plasma arc torch 19 is turned off and then the high frequency generator 5 with a certain temporal delay. Only when both plasma torches have been turned off is the vacuum chamber 3 ventilated. The contact with the oscillating circuit is broken and the part 1 or the parts 17 are transported out of the vacuum chamber 3.

### NOMENCLATURE

1 Part

2 Rail

3 Vacuum chamber

4 Insulation

5 High frequency generator

6 Coaxial cable

7 External oscillating circuit

8 High frequency supply lead

9 High frequency bushing

10 Reflector

11 Feedback coil

12 Capacitor of the external oscillating circuit

13 Coil

14 Coil

15 Grounding line

16 Transmitting tube

17 Part

18 Rack

19 Plasma arc torch

20 Plasma beam

21 Cathode

22 Anode

23 First expansion stage

24 Second expansion stage

25 Nozzle between cathode and anode

26 Feeder device

27 Feeder device

28 Opening

29 Recess

30 Funnel-shaped segment

31 Fastening part

1. Device for the plasma coating of large volume parts with a vacuum chamber with one or more pumps,
with a transport device for the conveyance of the part into the vacuum chamber,
with insulation between the part and the vacuum chamber,
with an oscillating circuit with a high frequency generator,
with an adjustable capacitance and an adjustable inductance of the oscillating circuit,
with at least one connection to connect the oscillating circuit with the part, and
with at least one plasma torch connected to the vacuum chamber for the preparation of a coating material for the part.

2. Apparatus as recited in claim 1, characterized in that the transport device has one or more rails and a drive system.

3. Apparatus as recited in claim 2, characterized in that the rails have an electrical insulation which insulates the part from the vacuum chamber.

4. Apparatus as recited in claim 1, characterized in that the oscillating circuit has one or more high frequency lines, and that high frequency bushings with electrical insulation for the high frequency lines are provided on the vacuum chamber.

5. Apparatus as recited in claim 1, characterized in that metal sheets and/or grids are provided in the vacuum chamber.

6. Apparatus as recited in claim 1, characterized in that the high frequency generator has a feedback coil with adjustable inductance.

7. Apparatus as recited in claim 1, characterized in that capacitances and/or inductances connected with the oscillating circuit via a switch are provided to tune the capacitance and/or the inductance of the oscillating circuit to the part.

8. Apparatus as recited in claim 1, characterized in that a transmitting tube is provided for the feed of the alternating current into the oscillating circuit.

9. Apparatus as recited in claim 1, characterized in that the plasma torch is a plasma arc torch with a cathode and an anode.

10. Apparatus as recited in claim 9, characterized in that the plasma arc torch has a plurality of expansion stages for the admixture of various coating materials.

11. Apparatus as recited in claim 10, characterized in that each expansion stage has a feed device for the introduction of a gas, a liquid and/or a powder into the plasma.

12. Apparatus as recited in claim 10, characterized in that a mixing chamber is located downstream from the expansion stages in the direction of flow.

13. Apparatus as recited in claim 12, characterized in that the plasma torch and the mixing chamber together form a double de Laval nozzle.

14. Apparatus as recited in claim 12, characterized in that the mixing chamber is connected as the anode or the mixing chamber has the same potential as the anode.

15. Method for the plasma coating of large-volume parts, in particular with the use of an apparatus as recited in one of the preceding claims, characterized in that
the part is located in a vacuum chamber and the vacuum chamber is evacuated,
the part is connected to an oscillating circuit with a high frequency generator,
the inductance and/or capacitance of the oscillating circuit is tuned to the part,
a plasma beam is generated by a plasma torch,
the coating material or materials are added to the plasma beam,
the plasma beam provided with the coating materials is introduced into the vacuum chamber.

16. Method as recited in claim 15, characterized in that the contact between the part and the oscillating circuit is verified by feeding a high frequency AC current at low power into the oscillating circuit.

17. Method as recited in claim 15, characterized in that an assist gas is fed into the vacuum chamber.

18. Method as recited in claim 15, characterized in that a liquid is vaporized and fed via a valve into the vacuum chamber.

19. Method as recited in one of the claims 15, characterized in that an alternating current voltage at 0.1 to 10 MHz, preferably between 1 and 4 MHz, is fed into the oscillating circuit via the high frequency generator.

20. Method as recited in one of the claims 15, characterized in that the vacuum chamber is evacuated to a pressure between 0.05 and 1,000 Pa.

21. Method as recited in one of the claims 15, characterized in that metal sheets and/or grids are positioned in the vacuum chamber.

22. Method as recited in one of the claims 15, characterized in that the plasma is adjusted to the surface of the part by variation of the anode voltage of a transmitting tube which feeds the alternating current into the oscillating circuit.

23. Method as recited in one of the claims 15, characterized in that additional capacitances and/or inductances in the oscillating circuit are used for the rough tuning of the oscillating circuit to the part.

24. Method as recited in one of the claims 15, characterized in that the inductance of the feedback coil of the oscillating circuit is used for the fine tuning of the oscillating circuit to the part.

25. Method as recited in one of the claims 15, characterized in that the inductance and the capacitance of the part are determined and that the inductance and the capacitance of the oscillating circuit are adjusted to the inductance and capacitance of the part.

26. Method as recited in one of the claims 15, characterized in that the plasma torch is provided with a plurality of expansion stages, and that through each of the expansion stages, a coating material or an ingredient of a coating material is fed to the plasma beam of the plasma torch.
